(19) United States
(12) Patent Application Publication
(10) Pub. No.: US 2024/0206289 A1
(43) Pub. Date: Jun. 20, 2024

(54) OPTICAL SOURCE ASSEMBLIES FOR USE WITH ORGANIC LIGHT-EMITTING DIODE (OLED) BASED SCREENS FOR MOBILE APPLICATIONS

(71) Applicant: II-VI Delaware, Inc., Wilmington, DE (US)

(72) Inventors: Michael A. Steib, Menlo Park, CA (US); Anna Tatarczak, Felton, CA (US)

(21) Appl. No.: 18/081,378

(22) Filed: Dec. 14, 2022

(51) Int. Cl. H10K 59/80

(52) U.S. Cl. CPC H10K 59/877; H10K 59/879

(57) ABSTRACT

Systems and methods are provided for optical source assemblies for use with organic light-emitting diode (OLED) based screens for mobile applications. A screen having one or more layers may be used in conjunction with a plurality of optical source assemblies embedded within or behind the screen, with the plurality of optical source assemblies configured to emit beams at certain locations within the screen, and where at least one of the one or more layers is configured to adjust or affect diffractive characteristics of beams emitted by the plurality of optical source assemblies. The screen may be an OLED based screen. The layers may include a thin-film-transistor (TFT) layer and an OLED layer. The TFT layer and/or the OLED layer may be configured to multiply emitter count on a projected area, and/or to shape emitter count and/or properties.

### TECHNICAL FIELD

Aspects of the present disclosure relate to energy generation and storage. More specifically, certain implementations of the present disclosure relate to methods and systems for optical source assemblies for use with organic light-emitting diode (OLED) based screens for mobile applications.

### BACKGROUND

Limitations and disadvantages of conventional and traditional devices and solutions for transmitting and receiving optical signals will become apparent to one of skill in the art, through comparison of such systems with some aspects of the present disclosure as set forth in the remainder of the present application with reference to the drawings.

### BRIEF SUMMARY

System and methods are provided for optical source assemblies for use with organic light-emitting diode (OLED) based screens for mobile applications, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example optical source assembly for use in organic light-emitting diode (OLED) based screens, in accordance with the present disclosure.

FIG. 2 illustrates an example use of multiple optical source assemblies within a screen, in accordance with the present disclosure.

FIG. 3 illustrates implementation of different components of a screen that is configured for supporting use of optical source assemblies, in accordance with the present disclosure.

FIGS. 4A-4B illustrate transmission distortions resulting from use of patterned layers in OLED based screens, in accordance with the present disclosure.

FIG. 5 illustrates effects of divergence angle for transmission distortions resulting from use of patterned layers in OLED based screens, in accordance with the present disclosure.

### DETAILED DESCRIPTION

Modern electronic equipment (e.g., cellphones, tablets, PC, etc.) use imaging displays with integrated light transmitters (e.g., flood illuminators for facial recognition, illuminators for time-of-flight 3D sensing, dot projectors for structured light 3D sensing, etc.) and receivers (e.g., RGB camera sensors, IR sensors, etc.). Currently, such transmitters and receivers are incorporated into an area of the screen, which reduces the area that is usable for imaging purposes. Note that the term screen is used interchangeably herein with the terms display, display screen and display layer. For example, cellphones may utilize a bevel on top of an OLED screen for that purpose. Improving performance of such screens, particularly in cost effective ways, is very desirable.

Accordingly, in various example implementations, solutions based on the present disclosure may be used in organic light-emitting diode (OLED) based screens to provide and/or enhance diffractive properties thereof. In this regard, a number of optical source assemblies may be incorporated within the screen, to provide beams only at certain locations within the screen (rather than the whole of the screens), with the remaining components of the screen being configured to support and enhance the diffractive characteristics of the beams emitted by these elements. Thus, solutions in accordance with the present disclosure allow for the elimination of dedicated diffractive components (e.g., diffractive optical elements) used in existing screens based on conventional solutions. In this regard, in a conventional screen, a diffractive optical element (DOE), which is a passive component, is used in conjunction with a beam source (e.g., vertical-cavity surface-emitting laser (VCSEL) based transmitter) that emits beam/light, which is focused onto the DOE, and which is then diffracted by the DOE. In accordance with the present disclosure, however, instead of using a DOE, a thin-film transistor (TFT) layer in the screen may be used as a diffractive optic layer to multiply projected beams count on a projected area. Similarly, an OLED layer in the screen may be used as a diffractive optic to further multiply and/or shape emitter count and properties. Thus, whereas an OLED based screen implemented based on existing solutions may comprise beam source (e.g., laser transmitter), diffractive optical element, TFT layers, OLED layers, and protective layers, an OLED based screen implemented based on the present disclosure would comprise only beam source (e.g., laser transmitter), TFT layers, OLED layers, and protective layers, with the TFT layers and/or the OLED layers therein being configured such as the diffractive properties thereof being used instead to obtain the same optical functions provided by the diffractive optical element.

In various example implementations, the pixel density, size, thickness, refractive index and arrangement of the OLED based screen may be modified to produce desired optical properties. The combination of a TFT and an OLED pixel assembly may be used in indirect Time-of-Flight (iToF), direct Time-of-Flight (dTof), structured light, etc. for beam manipulations. Multiple sources at different locations may be combined to increase depth range, reduce depth error and get higher resolutions. The patterns of the OLED and TFT allow higher transmission through the OLED/TFT to achieve better system performance (SNR, depth error). The present disclosure is applicable to any suitable type of laser, and as such example implementations based on the present disclosure may be used with, e.g., vertical-cavity surface-emitting laser (VCSEL), edge-emitting laser (EEL), distributed-feedback (DFB) laser, Fabry-Pérot (FP) laser, or any derivative thereof with diffractive optics in OLED layer stack.

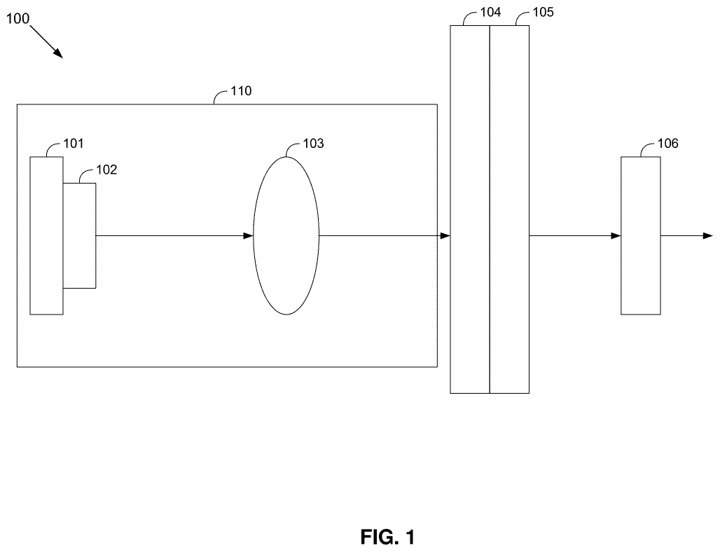

FIG. 1 illustrates an example optical source assembly for use in organic light-emitting diode (OLED) based screens, in accordance with the present disclosure. Shown in FIG. 1 is optical source assembly 100.

In this regard, the optical source assembly 100 may be configured for use in conjunction with screens, particularly OLED based screens, to facilitate or support diffractive optical related functions therein, such as by providing beams only at certain locations within the screen (rather than the whole of the screens). The remaining components of the screen may then be configured to support and enhanced the diffractive characteristics of the beams emitted by such elements.

As shown in FIG. 1, the optical source assembly 100 may be comprise a substrate 101, an optoelectronic device 102, and lens system 103. In this regard, the optical source assembly 100 may be comprise a packaging (or housing) 110 enclosing the various components of the optical source assembly 100. The substrate 101 holds electro-optical device(s) and/or any other component(s) of the optical source assembly 100. The optoelectronic device 102 is configured to emit beams. In this regard, the optoelectronic device 102 may be configured to emit beams at any wavelength, such as for depth cameras and/or bio-sensing applications. In this regard, the depth camera refers to receive (RX) and transmit (TX) sides. The lens system 103 is configured for beam shaping, to enable shaping of beams emitted by optoelectronic device 102 or received thereby.

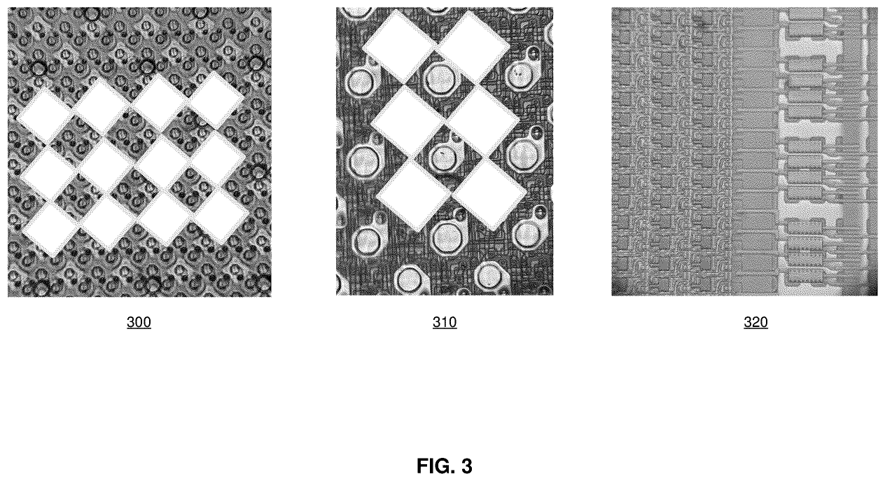

In operation, optical source assembly 100 be incorporated into screens or displays of electronic devices, particularly mobile devices (e.g., smartphones, tablets, etc.), with multiple instances thereof placed under the stacks/layers of the screens. In this regard, in various implementations, some of the components of the screens may be configured to operate in conjunction with optical source assemblies. For example, as illustrated in FIG. 1, the optical source assembly 100 may be placed behind (or under) the layers/stacks of a screen, which may comprise, e.g., patterned thin-film-transistor (TFT) layers/stacks 104, patterned/arranged organic light-emitting diode (OLED) layers/stacks 105, and top layers/stacks 106 (e.g., protective glass or the like) of the screen. As shown, the beam(s) emitted by the optical source assembly 100 may then pass through these layers/stacks of the screen. As such, at least some of these layers/stacks may be configured to further enhance and/or otherwise adjust the diffractive characteristics of the beams. This may be done, for example, by use of particular patterns or arrangements within these layers/stacks. Examples of such patterned layers/stacks are described in more detail below with respect to FIG. 3.

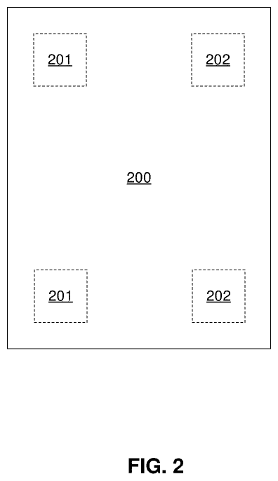

FIG. 2 illustrates an example use of multiple optical source assemblies within a screen, in accordance with the present disclosure. Shown in FIG. 2 is a screen 200 with multiple optical source assemblies placed at different screen locations 201-204.

In this regard, at each of screens 201, 202, 203, and 204, an optical source assembly and/or an electro-optical device, such as ones similar to the optical source assembly 100 of FIG. 1, may be implemented. Thus, as illustrated in FIG. 2, rather than implementing the screen 200 such that it would provide diffractive optical operation throughout the whole of the screen, only a number of DOEs may be used, being placed (e.g., embedded into the screen) instead at certain locations within the screen. It should be understood, however, that the arrangement illustrated in FIG. 2 is not limiting and as such any suitable arrangement (e.g., any number of DOEs and/or various placements thereof) may be used as long as it may provide desired or acceptable performance.

FIG. 3 illustrates implementation of different components of a screen that is configured for supporting use of optical source assemblies, in accordance with the present disclosure. Shown in FIG. 3 are (sections of) an organic light-emitting diode (OLED) layer 300, a thin-film-transistor (TFT) layer 310, and a sensory layer 320.

The OLED layer 300 comprises a plurality of pixel OLED elements. In this regard, as illustrated in FIG. 3, the OLED layer 300 comprises a plurality of rectangular pixel elements each comprising 4 sub-pixels (e.g., RGB) elements. The sensory layer 320 is configured for supporting certain functions in the screen, such as tactile related functions in touchscreens. In this regard, as shown in FIG. 3, the sensory layer 320 comprises suitable circuitry, such as a capacitive panel and thin-film-transistors.

As illustrated in FIG. 3, the different screen layers may be configured (e.g., patterned) to facilitate and/or support use of optical source assemblies, such as ones similar to the optical source assembly 100 of FIG. 1. In particular, the OLED layer 300 and the TFT layer 310 may incorporate patterns or arrangements (e.g., by use of cutout portions, as shown in FIG. 3) that are specifically selected or adjusted to support or optimized diffractive characteristics of emitted beams. In this regard, the patterns of the OLED layer 300 generate diffraction for beams associated with DOEs below (behind) the screen). Similarly, the patterns of the TFT layer 310 generate diffraction for the beams. As such, the combined patterned OLED/TFT may have higher transmission. Also, while not illustrated in FIG. 3, the sensory layer may also be patterned in similar manner to accommodate use, and further enhance operation of the DOEs.

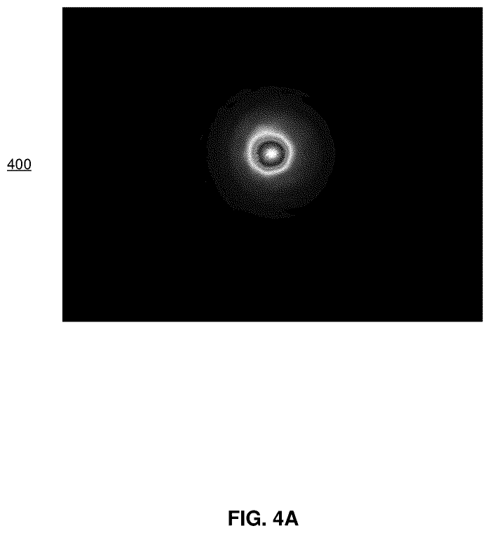

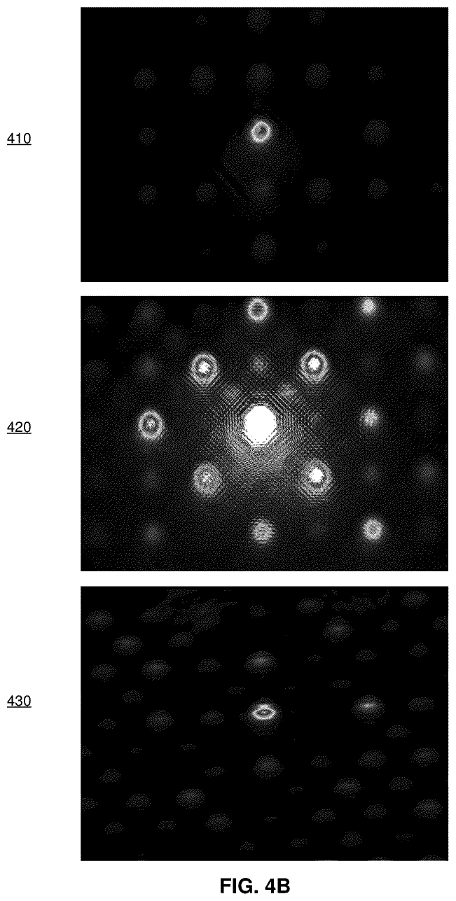

FIGS. 4A-4B illustrate transmission distortions resulting from use of patterned layers in OLED based screens, in accordance with the present disclosure. In particular, FIG. 4A illustrates a profile of a light beam used for the characterization of the OLED diffractive properties whereas FIG. 4B illustrates the transmission distortions resulting from use of patterned layers in OLED based screens in accordance with an example implementation based on the present disclosure.

Illustrated in FIGS. 4A-4B are screenshot images 400, 410, 420, and 430 (that is, images of a screen, or portion thereof, under certain operation conditions). In this regard, the screenshot images 400, 410, 420, and 430 are generated or obtained based on use of the same beam. For example, as shown in FIGS. 4A-4B, the screenshot image 400, 410, 420, and 430 are generated or obtained based on use of a 940 nm laser beam that is collimated and aligned with the sample. The screenshot image 400 depicts the outcome of use of the focused laser beam in a screen without use of optical source assemblies or use of patterned layers within the screen. The screenshot image 410 depicts the effects of diffraction after a patterned TFT layer (e.g., similar to the TFT layer 310 of FIG. 3) on the same beam. The screenshot image 420 depicts the effects of diffraction after a patterned OLED layer (e.g., similar to the OLED layer 300 of FIG. 3) on the same beam. The screenshot image 430 depicts the effects of diffraction after a patterned OLED layer (e.g., similar to the OLED layer 300 of FIG. 3) on the same beam.

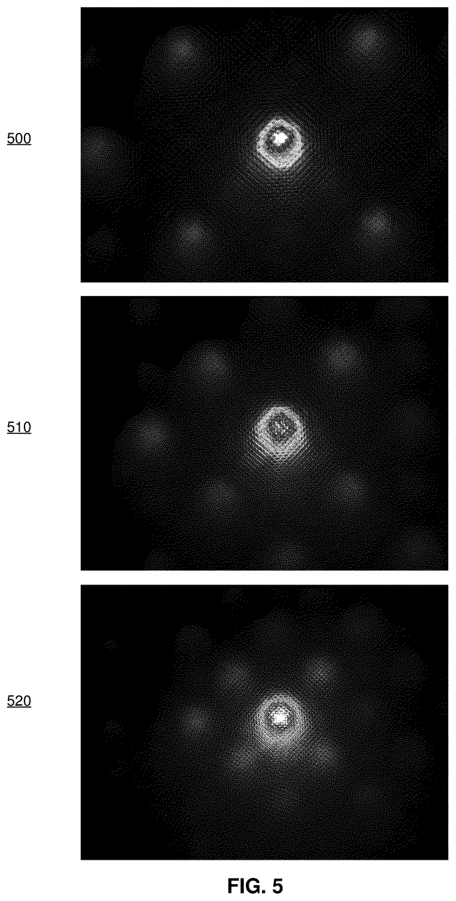

FIG. 5 illustrates effects of divergence angle for transmission distortions resulting from use of patterned layers in OLED based screens, in accordance with the present disclosure. Illustrated in FIG. 5 are screenshot images 500, 510, and 520 (that is, images of a screen, or portion thereof, under certain operation conditions).

In this regard, the screenshot images 500, 510, and 520 are generated or obtained based on use of the same beam in the same screen-specifically, a screen incorporating optical source assemblies and patterned layers within the screen, as described with respect to FIGS. 1 and 3, for example. The screenshot images 500, 510, and 520 correspond to placing of the screen at 3 different distances relative to the camera (or similar device) used in capturing the images. For example, as shown in FIG. 5, the screenshot images 500, 510, and 520 are generated or obtained at, respectively, distances of 20 cm, 13 cm, and 7 cm. As illustrated by the screenshot images 500, 510, and 520, the screen exhibits diffractive behavior that varies at different distances—that is, the screen has different divergence angles at different distances.

An example system, in accordance with the present disclosure, comprises a screen comprising one or more layers, and a plurality of optical source assemblies embedded within or behind the screen, with the plurality of optical source assemblies configured to emit beams at certain locations within the screen, and where at least one of the one or more layers is configured to adjust or affect diffractive characteristics of beams emitted by the plurality of optical source assemblies.

In an example embodiment, one or more characteristics of the screen are set or modified to produce optical properties based on preset criteria relating to diffractive performance.

In an example embodiment, the one or more characteristics comprise one or more of pixel density, size, thickness, refractive index, and arrangement.

In an example embodiment, the screen comprises an organic light-emitting diode (OLED) based screen.

In an example embodiment, the one or more layers comprise a thin-film-transistor (TFT) layer.

In an example embodiment, the thin-film transistor (TFT) layer is configured to multiply emitter count on a projected area.

In an example embodiment, the one or more layers comprise an organic light-emitting diode (OLED) layer.

In an example embodiment, the organic light-emitting diode (OLED) layer is configured to multiply and/or shape emitter count and/or properties.

In an example embodiment, the one or more layers comprise a sensory layer.

In an example embodiment, the one or more layers comprise a top protective layer.

In an example embodiment, the at least one of the one or more layers is physically patterned or arranged to adjust or affect diffractive characteristics of beams emitted by the plurality of optical source assemblies.

In an example embodiment, the physical patterning or arranging comprise use of cutout portions within the at least one of the one or more layers.

An example optical source assembly, in accordance with the present disclosure, comprises an optoelectronic component configured to emit beams, and a beam shaping component configured to shape beams emitted by the optoelectronic component, where the optical source assembly is configured for use in a screen, and is embedded at a particular location within or behind the screen.

In an example embodiment, the optical source assembly further comprises a housing or packaging configured to enclose all remaining components of the optical source assembly.

In an example embodiment, the optical source assembly further comprises a substrate.

In an example embodiment, the optoelectronic component is embedded onto the substrate.

In an example embodiment, the beam shaping component comprises a lens based component.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic components (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system comprising:
a screen comprising one or more layers; and
a plurality of optical source assemblies embedded within or behind the screen;
wherein the plurality of optical source assemblies are configured to emit beams at certain locations within the screen; and
wherein at least one of the one or more layers is configured to adjust or affect diffractive characteristics of beams emitted by the plurality of optical source assemblies.

2. The system of claim 1, wherein one or more characteristics of the screen are set or modified to produce optical properties based on preset criteria relating to diffractive performance.

3. The system of claim 2, wherein the one or more characteristics comprise one or more of pixel density, size, thickness, refractive index, and arrangement.

4. The system of claim 1, wherein the screen comprises an organic light-emitting diode (OLED) based screen.

5. The system of claim 1, wherein the one or more layers comprise a thin-film-transistor (TFT) layer.

6. The system of claim 5, wherein the thin-film transistor (TFT) layer is configured to multiply emitter count on a projected area.

7. The system of claim 1, wherein the one or more layers comprise an organic light-emitting diode (OLED) layer.

8. The system of claim 7, wherein the organic light-emitting diode (OLED) layer is configured to multiply and/or shape emitter count and/or properties.

9. The system of claim 1, wherein the one or more layers comprise a sensory layer.

10. The system of claim 1, wherein the one or more layers comprise a top protective layer.

11. The system of claim 1, wherein the at least one of the one or more layers is physically patterned or arranged to adjust or affect diffractive characteristics of beams emitted by the plurality of optical source assemblies.

12. The system of claim 1, wherein the physical patterning or arranging comprise use of cutout portion portions within the at least one of the one or more layers.

13. An optical source assembly comprising:
an optoelectronic component configured to emit beams; and
a beam shaping component configured to shape beams emitted by the optoelectronic component;
wherein the optical source assembly is configured for use in a screen and is embedded at a particular location within or behind the screen.

14. The optical source assembly of claim 13, further comprising a housing or packaging configured to enclose all remaining components of the optical source assembly.

15. The optical source assembly of claim 13, further comprising a substrate.

16. The optical source assembly of claim 15, wherein the optoelectronic component is embedded onto the substrate.

17. The optical source assembly of claim 13, wherein the beam shaping component comprises a lens based component.
